(19) United States
(12) Patent Application Publication
(10) Pub. No.: US 2024/0327983 A1
(43) Pub. Date: Oct. 3, 2024

(54) PROCESSING SYSTEMS FOR METAL PRECURSOR SYNTHESIS AND DEPOSITION

(71) Applicant: Applied Materials, Inc., Santa Clara, CA (US)

(72) Inventor: Andrea Leoncini, Singapore (SG)

(73) Assignee: Applied Materials, Inc., Santa Clara, CA (US)

(21) Appl. No.: 18/609,267

(22) Filed: Mar. 19, 2024

Related U.S. Application Data
(60) Provisional application No. 63/456,081, filed on Mar. 31, 2023.

(51) Int. Cl. C23C 16/455; C23C 16/458

(52) U.S. Cl. CPC C23C 16/45553; C23C 16/458

(57) ABSTRACT

Processing chambers for forming metal-containing precursors and deposition of pure metal films are disclosed. Also disclosed are deposition methods that include forming a metal-containing precursor and depositing the metal-containing precursor on a substrate to form a metal film in a single processing chamber.

### CROSS-REFERENCE TO RELATED APPLICATIONS

This application claims priority to U.S. Provisional Application No. 63/456,081, filed Mar. 31, 2023, the entire disclosure of which is hereby incorporated by reference herein.

### TECHNICAL FIELD

Embodiments of the present disclosure generally relate to processing systems for use in semiconductor device formation processes. In particular, embodiments of the disclosure relate to processing systems for metal precursor synthesis and deposition of metal films.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

Sputtering is a physical vapor deposition (PVD) process in which high-energy ions impact and erode a solid target and deposit the target material on the surface of a substrate, such as a semiconductor substrate. In semiconductor fabrication, the sputtering process is usually accomplished within a semiconductor fabrication chamber also known as a PVD process chamber or a sputtering chamber. Sputtering has long been used for the deposition of metals and related materials in the fabrication of semiconductor integrated circuits.

Typically, the sputtering chamber comprises an enclosure wall that encloses a process zone into which a process gas is introduced, a gas energizer to energize the process gas, and an exhaust port to exhaust and control the pressure of the process gas in the chamber. The chamber is used to sputter deposit a material from a sputtering target onto the substrate. In the sputtering processes, the sputtering target is bombarded by energetic ions, such as a plasma, causing material to be knocked off the target and deposited as a film on the substrate.

A typical semiconductor fabrication chamber has a target assembly including disc-shaped target of solid metal or other material supported by a backing plate that holds the target. To promote uniform deposition, the PVD chamber may have an annular concentric metallic ring, which is often called a shield, circumferentially surrounding the disc-shaped target.

Plasma sputtering may be accomplished using either DC sputtering or RF sputtering. Plasma sputtering typically includes a magnetron positioned at the back of a sputtering target including two magnets of opposing poles magnetically coupled at their back through a magnetic yoke to project a magnetic field into the processing space to increase the density of the plasma and enhance the sputtering rate from a front face of the target. Magnets used in the magnetron are typically closed loop for DC sputtering and open loop for RF sputtering.

In plasma-enhanced substrate processing systems, such as physical vapor deposition (PVD) chambers, high power density PVD sputtering with high magnetic fields and high DC power can produce high energy at a sputtering target, and cause a large rise in surface temperature of the sputtering target. The sputtering target is cooled by contacting a target backing plate with cooling fluid. In plasma sputtering as typically practiced commercially, a target of the material to be sputter deposited is sealed to a vacuum chamber containing the substrate to be coated. An inert gas, such as argon, may be admitted to the chamber. When a negative DC bias of several hundred volts is applied to target while the chamber walls or shields remain grounded, the argon is excited into a plasma. The positively charged argon ions are attracted to the negatively biased target at high energy and sputter target atoms (e.g., metal atoms) from the target.

Chemical vapor deposition (CVD) is one of the most common deposition processes employed for depositing layers on a substrate. CVD is a flux-dependent deposition technique that requires precise control of the substrate temperature and the precursors introduced into the processing chamber in order to produce a desired layer of uniform thickness. These requirements become more critical as substrate size increases, creating a need for more complexity in chamber design and gas flow technique to maintain adequate uniformity.

A variant of CVD that demonstrates excellent step coverage is cyclical deposition or atomic layer deposition (ALD). Cyclical deposition is based upon atomic layer epitaxy (ALE) and employs chemisorption techniques to deliver precursor molecules on a substrate surface in sequential cycles. The cycle exposes the substrate surface to a first precursor, a purge gas, a second precursor and the purge gas. The first and second precursors react to form a product compound as a film on the substrate surface. The cycle is repeated to form the layer to a desired thickness.

The advancing complexity of advanced microelectronic devices is placing stringent demands on currently used deposition techniques. Unfortunately, there is a limited number of viable chemical precursors available that have the requisite properties of robust thermal stability, high reactivity, and vapor pressure suitable for film growth to occur. In addition, precursors that often meet these requirements still suffer from poor long-term stability and lead to thin films that contain elevated concentrations of contaminants such as oxygen, nitrogen, and/or halides that are often deleterious to the target film application.

Metal-containing precursors for ALD films, for example, are often thermally unstable, have halogens, add impurities to the film, or include a metal in non-zero oxidation state. For some elements, it is challenging to reduce to zero oxidation state in an ALD chamber. Without intending to be bound by theory, it is thought that these problems make the deposition of pure metal films impractical using conventional techniques which require chemical synthesis of expensive organometallic compounds, or the use of metal halides (when volatile).

Accordingly, there is a need for improved processing chambers for forming viable metal-containing precursors and deposition of pure metal films.

### SUMMARY

One or more embodiments of the disclosure relate to a processing chamber. The processing chamber comprises a chamber body having a top wall, a bottom wall, and two opposed sidewalls containing an interior volume; a metal source within the interior volume to provide metal atoms to a precursor formation region within the interior volume; and a ligand source to provide vaporized ligands to the precursor formation region. The metal atoms and the vaporized ligands react in the precursor formation region to form a metal-containing precursor.

Additional embodiments of the disclosure relate to a processing chamber. The processing chamber comprises a chamber body having a top wall, a bottom wall, and two opposed sidewalls containing an interior volume; a metal source within the interior volume to provide metal atoms to a precursor formation region within the interior volume; and a ligand source to provide vaporized ligands to the precursor formation region. The metal atoms and the vaporized ligands react in the precursor formation region to form a metal-containing precursor. A substrate is positioned on a substrate support within the interior volume, and the metal-containing precursor forms a metal film on the substrate.

Further embodiments of the disclosure relate to a deposition method. The deposition method comprises forming a metal-containing precursor by providing metal atoms to a precursor formation region from a metal source, the metal source and the precursor formation region within an interior volume of a processing chamber, and providing vaporized ligands to the precursor formation region from a ligand source. The metal atoms and the vaporized ligands react in the precursor formation region to form the metal-containing precursor. The deposition method further comprises exposing a substrate surface to the metal-containing precursor to deposit a metal film.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments.

FIG. 1 illustrates a schematic cross-sectional view of a processing chamber according to one or more embodiments of the disclosure;

FIG. 2 illustrates a schematic cross-sectional view of a processing chamber according to one or more embodiments of the disclosure; and

FIG. 3 illustrates a cluster tool according one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

In extreme ultraviolet (EUV) lithography (EUVL), which can be used for the manufacture of 0.0135 micron and smaller minimum feature size semiconductor devices, a thin pellicle is used during manufacture of integrated circuits. More specifically, in EUVL a photomask, e.g., a reticle, may be repeatedly used to reproducibly print thousands of substrates to form integrated circuits. Typically, a reticle is a glass or a quartz substrate including a film stack having multiple layers, including a light-absorbing layer and an opaque layer disposed thereon. A pellicle is used to protect the reticle from particle contamination by mounting the pellicle a few millimeters above the photomask surface, mechanically separating particles from the photomask surface. A pellicle is a thin transparent membrane which allows light and radiation to pass therethrough to the reticle and which is stretched above and not touching the surface of the mask. In one or more embodiments, the reticle is a glass substrate. In one or more embodiments, the reticle is a quartz substrate.

A key feature of an EUV pellicle is that the pellicle permits transmission of EUV light to ensure the productivity of the EUV lithography system, for example, at least 90% transmission of EUV light (e.g., at the 13.5 nm exposure wavelength). Low transmission reduces the effective exposure power and thwarts productivity of the EUVL system. The pellicle also needs to be mechanically stable, which is difficult to achieve for membranes that are thin enough to meet EUV transmission requirements. The thin membrane is mounted on a frame and fixed to the photomask. Pellicles comprising carbon nanotube (CNT) membranes have been used in EUVL. In some embodiments, the substrate comprises at least one EUV pellicle. In some embodiments, the substrate comprises at least one EUV pellicle, and each EUV pellicle independently comprises at least one carbon nanotube (CNT) membrane.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface are exposed simultaneously to the two or more reactive compounds so that no given point on the substrate is exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second reactive gas (i.e., a second precursor or compound B) is pulsed into the reaction zone followed by a second delay. During each time delay, a purge gas, such as argon or helium, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive gases are alternatively pulsed until a desired film or film thickness is formed on the substrate surface. In either scenario, the ALD process of pulsing compound A, purge gas, compound B and purge gas is referred to as a cycle. A cycle can start with either compound A or compound B and continue the respective order of the cycle until achieving a film with the predetermined thickness.

A “pulse” or “dose” as used herein is intended to refer to a quantity of a source gas that is intermittently or non-continuously introduced into the process chamber. The quantity of a particular compound within each pulse may vary over time, depending on the duration of the pulse. A particular process gas may include a single compound or a mixture/combination of two or more compounds.

The durations for each pulse/dose are variable and may be adjusted to accommodate, for example, the volume capacity of the processing chamber as well as the capabilities of a vacuum system coupled thereto. Additionally, the dose time of a process gas may vary according to the flow rate of the process gas, the temperature of the process gas, the type of control valve, the type of process chamber employed, as well as the ability of the components of the process gas to adsorb onto the substrate surface. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

In some embodiments, the reactant comprises an inert, diluent and/or carrier gas. The inert, diluent and/or carrier gas may be mixed with the reactive species and can be pulsed or have a constant flow. In some embodiments, the carrier gas is flowed into the processing chamber at a constant flow in the range of about 1 to about 20000 sccm. The carrier gas may be any gas which does not interfere with the film deposition. For example, the carrier gas may comprise one or more of argon, helium, nitrogen, neon, or the like, or combinations thereof. In one or more embodiments, the carrier gas is mixed with the reactive species prior to flowing into the reservoir.

The processing chambers of the present disclosure may be used as part of any known deposition technique. In some embodiments, the processing chambers are used in atomic layer deposition (ALD) processes, chemical vapor deposition (CVD) processes, pulsed CVD processes, plasma-enhanced atomic layer (PEALD) processes, and/or plasma-enhanced chemical vapor deposition (PECVD) processes.

Embodiments of the present disclosure advantageously avoid the challenges related to the use of metal halides, non-zero oxidation states, precursor stability in ampoules, and precursor synthesis. Provided are processing systems for forming metal precursors directly in gas phase from a pure metal and a ligand.

In some embodiments, vaporized metal atoms are captured by ligands, which keep them in gas phase and carry them to a separate deposition chamber, or to a substrate. Weaker ligands form metastable complexes which are suitable for a CVD process; stronger ligands will be more suitable for ALD processes.

Some embodiments of the disclosure advantageously provide for the delivery of higher precursor concentrations in a shorter period of time relative to current processing systems.

Some embodiments of the disclosure advantageously provide apparatuses and methods which have the ability to burst a high dose of chemistry onto a substrate or into a separate processing chamber. High burst delivery processes may be useful for deposition on high surface area structured wafers.

Some embodiments advantageously provide for greater control over the amount of precursor delivered to a substrate, or a separate process chamber during a deposition process. Some embodiments of the disclosure advantageously provide for the delivery of more consistent precursor concentrations over time during a semiconductor substrate processing method.

Some embodiments of the disclosure advantageously provide apparatus for in-situ precursor formation. Some embodiments provide apparatus that decrease precursor expenses by formation of the metal precursor in-situ. In some embodiments, the metal precursor is formed immediately prior to deposition in either the same chamber as the substrate or in an adjacent chamber and flowed into the processing chamber with the substrate. In some embodiments, the metal precursor is formed in the vapor phase and maintained in the vapor phase by suitable heating of the chamber walls and/or gas lines connecting the synthesis chamber with the deposition chamber.

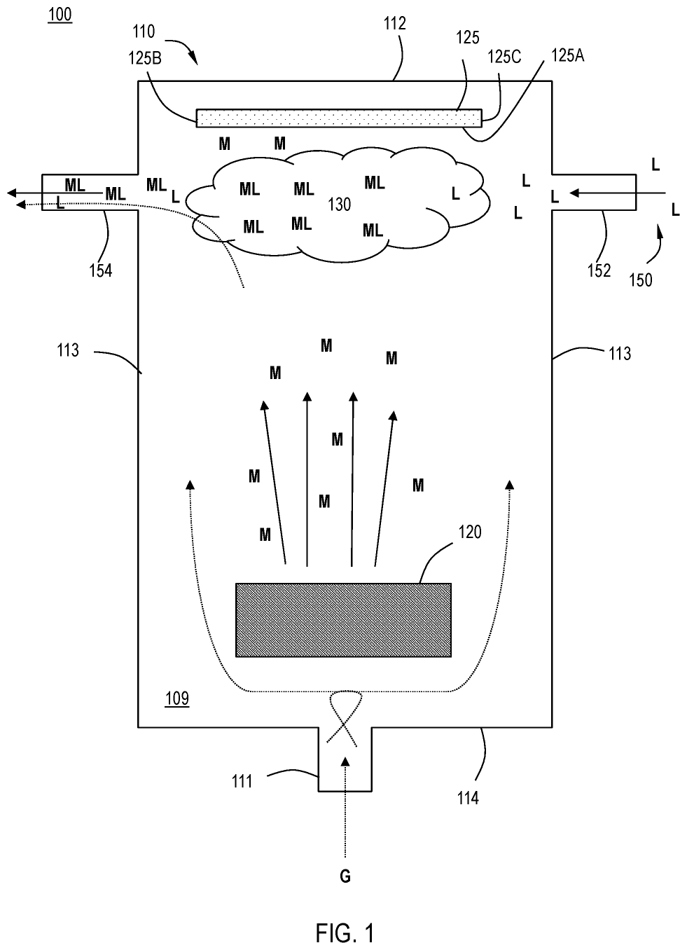

In some embodiments, the processing systems, such as processing chamber 100 shown in FIG. 1, comprise a chamber body 110 having a top wall 112, a bottom wall 114, and two opposed sidewalls 113 containing an interior volume 109. The processing chamber 100 may also be referred to as a synthesis chamber. The arrangement of components illustrated in the Figures exemplifies one possible configuration and should not be taken limiting the scope of the disclosure.

The processing chamber 100 includes a metal source 120 (e.g., a PVD source of a desired metal) within the interior volume 109 to provide metal atoms (M) to a precursor formation region 130 within the interior volume 109. In some embodiments, the metal source 120 is a PVD source. The PVD source 120 may include, but is not limited to, a magnetron sputter, thermal evaporator, or an e-beam.

In some embodiments, the PVD source 120 faces a sacrificial substrate/sacrificial target 125. In some embodiments, the sacrificial target 125 is spaced a distance from the metal source 120 on a side opposite of the precursor formation region 130. In some embodiments the sacrificial target 125 comprises a front face 125A extending between peripheral edges 125B, 125C, of the target 125. During processing, the metal source 120 provides metal atoms M to the precursor formation region 130 and some metal atoms M to the front face 125A of the sacrificial target 125.

During processing, a stream of gas containing the vaporized ligands (L) flows from a ligand source 150 through an inlet 152 perpendicular to the metal atom (M) direction, to the precursor formation region 130, in front of the sacrificial target 125. Stated differently, in some embodiments, the direction of the flow of metal atoms M from the PVD source 120 to the sacrificial target 125, denoted by vertically aligned arrows, is perpendicular to the flow of the vaporized ligands L from the ligand source 150 to a desired target direction, such as an outlet 154, denoted by horizontally aligned arrows. The metal atoms M captured by the vaporized ligands L in the precursor formation region 130 will form a metal-containing precursor that will follow the gas flow out of the processing chamber 100 through an outlet 154, towards a deposition chamber, such as an ALD chamber, while some metal atoms M will deposit on the front face 125A of the sacrificial target 125. In some embodiments, the outlet 154, and gas lines connecting the outlet 154 with a downstream deposition chamber are heated or thermally insulated to prevent condensation of the metal precursor (ML) formed in precursor formation region 130.

The metal atoms M may be sputtered from the PVD source 120 to the precursor formation region 130 and the sacrificial target 125 at any suitable pressure. In some embodiments, the metal atoms M are sputtered at a pressure in a range of from about 0.1 mtorr to 1 Torr, such as, for example, at a pressure in a range of from about 10 mtorr to 1 Torr. In some embodiments, the PVD source 120 can be protected by an inert gas curtain to prevent target contamination.

In some embodiments, the metal atoms M are carried in an inert gas G from a gas inlet 111. In some embodiments, the gas inlet 111 is positioned along the bottom wall 114, below the PVD source 120. In some embodiments, the gas inlet 111 is positioned outside of the interior volume 109, along the bottom wall 114, below the PVD source 120. In some embodiments, the inert gas G is selected from the group consisting of helium (He), neon (Ne), argon (Ar), and krypton (Kr). In some embodiments, the inert gas G is argon (Ar).

The inlet 152 for the gas carrying the vaporized ligands L may be positioned away from the PVD source 120. In some embodiments, the inlet 152 for the gas carrying the vaporized ligands L is positioned along one of the two opposed sidewalls 113 of the chamber body 110. After a predetermined amount of time, the sacrificial target 125 can be removed and sent for metallurgic recovery of metal atoms M. The metallurgic recovery process may be any suitable process known to the skilled artisan.

The metal atoms may include any metal known to the skilled artisan. In some embodiments, the metal atoms comprise a transition metal. In some embodiments, the transition metal is one or more of molybdenum (Mo), tungsten (W), ruthenium (Ru), cobalt (Co), copper (Cu), chromium (Cr), or nickel (Ni). In some embodiments, the transition metal is molybdenum (Mo). Molybdenum (Mo), for example, has attractive material and conductive properties for front end to back end parts of semiconductor and microelectronic devices.

In some embodiments, the metal atoms M and the sacrificial target 125 comprise the same material. In some embodiments, the metal atoms M and the sacrificial target 125 comprise a transition metal. In some embodiments, the metal atoms M and the sacrificial target 125 comprise molybdenum (Mo). Without intending to be bound by theory, it is thought that when the metal atoms M and the sacrificial target 125 comprise the same material, such as a transition metal, the sacrificial target 125 can be removed and sent for metallurgic recovery of metal atoms M, and the metal atoms M can be reused. The metallurgic recovery process performed on the removed sacrificial target 125 may be any suitable process known to the skilled artisan.

The vaporized ligands L may include any ligand known to the skilled artisan. In some embodiments, the vaporized ligands L include, but are not limited to, substituted or unsubstituted alkenes and alkynes, imines, heterocyclic compounds, chelating ligands, unsubstituted or substituted arenes, tertiary amines, tertiary phosphines, ethers, dienes, or combinations thereof.

In some embodiments, the metal atoms M and the vaporized ligands L react in the precursor formation region 130 to form a metal-containing precursor. The metal-containing precursors of one or more embodiments advantageously avoid additional process for metal reduction, are free of halogens, are free of a metal-oxygen bonds, are thermally stable for delivery, have high vapor pressure, are deliverable by vapor methods, are reactive for ALD processes at low temperatures (<400° C.), and achieve successful synthesis in one step with high yield and purity.

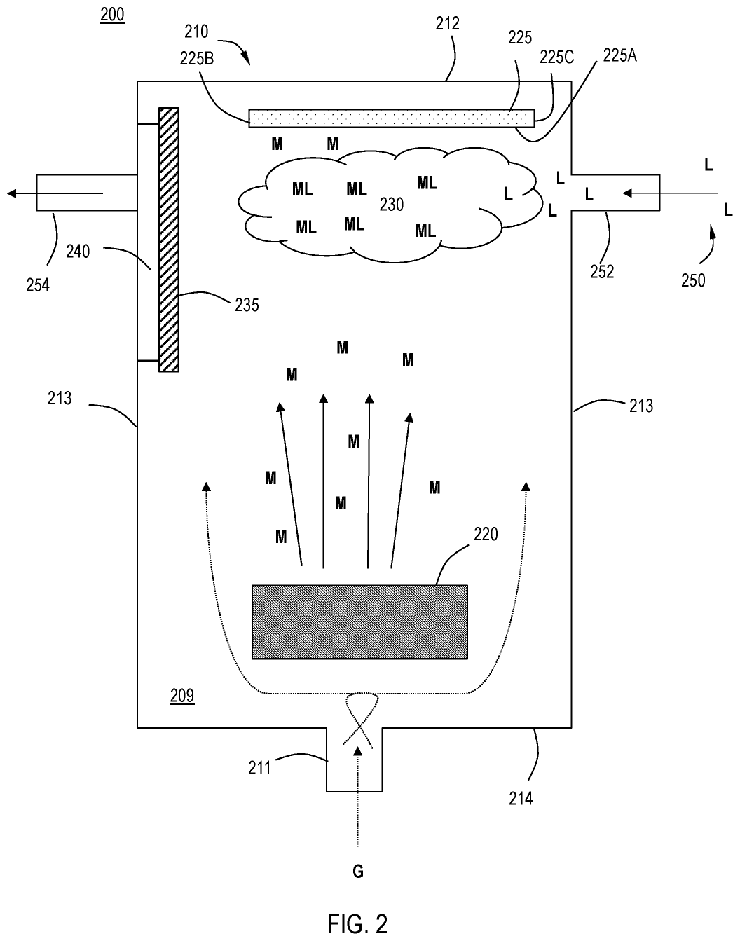

In some embodiments, the synthesis of the metal-containing precursors and the deposition of a metal film advantageously occurs in a single chamber, such as processing chamber 200. The processing chamber 200 may have one or more of the same features as processing chamber 100 shown in FIG. 1, and similar or same features may be denoted by like reference numbers. For example, the sacrificial target 125 shown in FIG. 1 may have the same properties as the sacrificial target 225 shown in FIG. 2.

In some embodiments, the processing chamber 200 shown in FIG. 2 comprises a chamber body 210 having a top wall 212, a bottom wall 214, and two opposed sidewalls 213 containing an interior volume 209.

The processing chamber 200 includes a metal source 220 (e.g., a PVD source of a desired metal) within the interior volume 209 to provide metal atoms (M) to a precursor formation region 230 within the interior volume 209. In some embodiments, the metal source 220 is a PVD source. The PVD source 220 may include, but is not limited to, a magnetron sputter, thermal evaporator, or an e-beam. In some embodiments, the PVD source 220 faces a sacrificial substrate/sacrificial target 225. In some embodiments, the sacrificial target 225 is spaced a distance from the metal source 220 on a side opposite of the precursor formation region 230. In some embodiments the sacrificial target 225 comprises a front face 225A extending between peripheral edges 225B, 225C, of the target 225. During processing, the metal source 220 provides metal atoms M to the precursor formation region 230 and some metal atoms M to the front face 225A of the sacrificial target 225.

During processing, a stream of gas containing the vaporized ligands (L) flows from a ligand source 250 through an inlet 252 perpendicular to the metal atom (M) direction, to the precursor formation region 230, in front of the sacrificial target 225. Stated differently, in some embodiments, the direction of the flow of metal atoms M from the PVD source 220 to the sacrificial target 225, denoted by vertically aligned arrows, is perpendicular to the flow of the vaporized ligands L from the ligand source 250 to a desired target direction, such as a substrate 235 and/or an outlet 254, denoted by horizontally aligned arrows. The metal atoms M captured by the vaporized ligands L in the precursor formation region 230 will form a metal-containing precursor. The processing chamber 200 comprises a substrate 235 supported by a substrate support 240 within the chamber body 210. The substrate support 240 may be electrically floating or may be biased by a pedestal power supply (not shown).

In some embodiments, the metal atoms M captured by the vaporized ligands L in the precursor formation region 230 that form the metal-containing precursor continue to flow and form a metal film on the substrate 235.

The semiconductor substrate 235 can be any suitable substrate material. In one or more embodiments, the semiconductor substrate 235 comprises a semiconductor material, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), copper indium gallium selenide (CIGS), other semiconductor materials, or any combination thereof. In one or more embodiments, the semiconductor substrate 235 comprises one or more of silicon (Si), germanium (Ge), gallium (Ga), arsenic (As), indium (In), phosphorus (P), copper (Cu), or selenium (Se). Although a few examples of materials from which the semiconductor substrate 235 may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

The metal film, formed from the metal-containing precursor, may comprise a transition metal. In some embodiments, the metal film comprises one or more of molybdenum (Mo), tungsten (W), ruthenium (Ru), cobalt (Co), copper (Cu), chromium (Cr), or nickel (Ni). Molybdenum (Mo), for example, can be grown by atomic layer deposition (ALD) or chemical vapor deposition (CVD) for many applications. One or more embodiments of the disclosure advantageously provide processes for atomic layer deposition (ALD) or chemical vapor deposition (CVD) to form molybdenum-containing films.

In one or more embodiments, the metal film comprises greater than or equal to 90% metal, greater than or equal to 95% metal, greater than or equal to 99% metal, or greater than or equal to 99.9% metal, on a molar basis. Stated differently, a molybdenum-containing film comprising greater than or equal to 90% metal, greater than or equal to 95% metal, greater than or equal to 99% metal, or greater than or equal to 99.9% metal, for example, means that greater than or equal to 90%, greater than or equal to 95%, greater than or equal to 99%, or greater than or equal to 99.9% of the atoms in the stated metal containing film include the stated metal species.

The deposition can be repeated in the processing chamber 200 to form a metal film having a predetermined thickness. In some embodiments, the deposition is repeated to provide a metal film, such as a molybdenum film, having a thickness in the range of about 0.3 nm to about 100 nm, or in the range of about 30 Å to about 10 μm.

The metal film formed on the substrate 235 may be patterned and etched or followed by bulk metal deposition to form interconnecting layers in a semiconductor wafer.

In some embodiments, some of the metal atoms M and some of the vaporized ligands L do not react in the precursor formation region 230 and flow out of the processing chamber 200 through an outlet 254, while some metal atoms M will deposit on the front face 225A of the sacrificial target 225. In one or more embodiments, the outlet 254 is a purge outlet where purge gases are flown in to facilitate the removal of unreacted metal atoms M and/or unreacted vaporized ligands L.

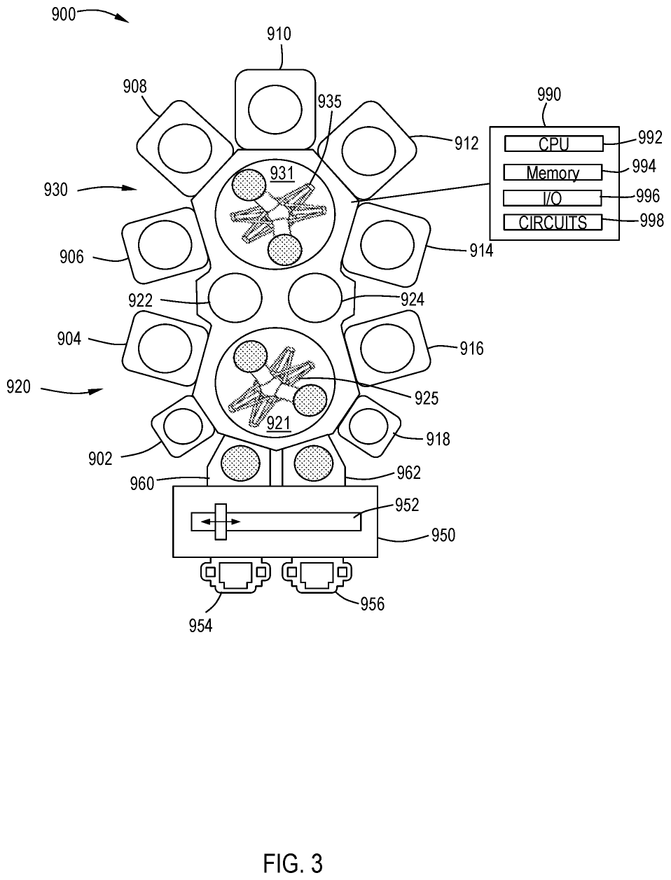

Additional embodiments of the disclosure are directed to cluster tools 900 for the formation of a semiconductor device using process chambers 100, 200, and the methods described, as shown in FIG. 3.

The cluster tool 900 includes at least one central transfer station 921, 931 with a plurality of sides. A robot 925, 935 is positioned within the central transfer station 921, 931 and is configured to move a robot blade and a wafer to each of the plurality of sides.

The cluster tool 900 comprises a plurality of processing chambers 902, 904, 906, 908, 910, 912, 914, 916, and 918, also referred to as process stations, connected to the central transfer station. The various processing chambers provide separate processing regions isolated from adjacent process stations. The processing chamber can be any suitable chamber including, but not limited to, a preclean chamber, a buffer chamber, transfer space(s), a wafer orienter/degas chamber, a cryo cooling chamber, a deposition chamber, annealing chamber, etching chamber, a selective oxidation chamber, an oxide layer thinning chamber, or a word line deposition chamber. The particular arrangement of process chambers and components can be varied depending on the cluster tool and should not be taken as limiting the scope of the disclosure.

In the embodiment shown in FIG. 3, a factory interface 950 is connected to a front of the cluster tool 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the cluster tool 900. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock 962 and the unloading chamber 956.

The cluster tool 900 shown has a first section 920 and a second section 930. The first section 920 is connected to the factory interface 950 through load lock chambers 960, 962. The first section 920 includes a first transfer chamber 921 with at least one robot 925 positioned therein. The robot 925 is also referred to as a robotic wafer transport mechanism. The first transfer chamber 921 is centrally located with respect to the load lock chambers 960, 962, process chambers 902, 904, 916, 918, and buffer chambers 922, 924. The robot 925 of some embodiments is a multi-arm robot capable of independently moving more than one wafer at a time. In some embodiments, the first transfer chamber 921 comprises more than one robotic wafer transfer mechanism. The robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930 or allow water cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit, memory, suitable circuits, and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

In one or more embodiments, a processing tool, such as the cluster tool 900, comprises: a central transfer station comprising a robot configured to move a wafer; a plurality of process stations, each process station connected to the central transfer station and providing a processing region separated from processing regions of adjacent process stations, the plurality of process stations comprising the processing chamber 100 and a deposition chamber, such as a chemical vapor deposition (CVD) chamber and/or an atomic layer deposition (ALD) chamber; and a controller connected to the central transfer station and the plurality of process stations, the controller configured to activate the robot to move the wafer between process stations, and to control a process occurring in each of the process stations.

In one or more embodiments, a processing tool comprises: a central transfer station comprising a robot configured to move a wafer; a plurality of process stations, each process station connected to the central transfer station and providing a processing region separated from processing regions of adjacent process stations, the plurality of process stations comprising the processing chamber 200 which includes a deposition chamber, such as a chemical vapor deposition (CVD) chamber and/or an atomic layer deposition (ALD) chamber, where the synthesis of the metal-containing precursors and the deposition of a metal film occurs in a single chamber; and a controller connected to the central transfer station and the plurality of process stations, the controller configured to activate the robot to move the wafer between process stations, and to control a process occurring in each of the process stations.

Further embodiments of the disclosure relate to a deposition method. The deposition method comprises forming a metal-containing precursor by providing metal atoms to a precursor formation region from a metal source, the metal source and the precursor formation region within an interior volume of a processing chamber, and providing vaporized ligands to the precursor formation region from a ligand source. The metal atoms and the vaporized ligands react in the precursor formation region to form the metal-containing precursor. The deposition method further comprises exposing a substrate surface to the metal-containing precursor to deposit a metal film.

One or more embodiments provide a non-transitory computer readable medium including instructions, that, when executed by a controller of a processing chamber, causes the processing chamber to perform the operations of the methods described herein. Further embodiments provide a non-transitory computer readable medium including instructions, that, when executed by a controller of a processing chamber, causes the processing chamber to perform the operations of the deposition method described herein, which comprises forming a metal-containing precursor by providing metal atoms to a precursor formation region from a metal source, the metal source and the precursor formation region within an interior volume of a processing chamber, and providing vaporized ligands to the precursor formation region from a ligand source. The metal atoms and the vaporized ligands react in the precursor formation region to form the metal-containing precursor. The deposition method further comprises exposing a substrate surface to the metal-containing precursor to deposit a metal film.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods, and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A processing chamber comprising:
a chamber body having a top wall, a bottom wall, and two opposed sidewalls containing an interior volume;
a metal source within the interior volume to provide metal atoms to a precursor formation region within the interior volume; and
a ligand source to provide vaporized ligands to the precursor formation region, wherein the metal atoms and the vaporized ligands react to form a metal-containing precursor.

2. The processing chamber of claim 1, wherein the vaporized ligands flow perpendicular to the metal atoms.

3. The processing chamber of claim 1, wherein the metal source is a physical vapor deposition (PVD) source.

4. The processing chamber of claim 3, wherein the PVD source comprises one or more of a magnetron sputter, a thermal evaporator, or an e-beam.

5. The processing chamber of claim 3, wherein the PVD source provides the metal atoms to the target at a pressure in a range of from about 0.1 mtorr to 1 Torr.

6. The processing chamber of claim 1, wherein the metal atoms are carried in an inert gas selected from the group consisting of helium (He), neon (Ne), argon (Ar), and krypton (Kr).

7. The processing chamber of claim 1, wherein the metal atoms comprise a transition metal.

8. The processing chamber of claim 7, wherein the transition metal is one or more of molybdenum (Mo), tungsten (W), ruthenium (Ru), cobalt (Co), copper (Cu), chromium (Cr), or nickel (Ni).

9. The processing chamber of claim 1, further comprising a sacrificial target spaced a distance from the metal source on a side opposite of the precursor formation region.

10. The processing chamber of claim 9, wherein the sacrificial target comprises a front face extending between peripheral edges of the target.

11. The processing chamber of claim 10, wherein some of the metal atoms are deposited on the front face of the sacrificial target.

12. The processing chamber of claim 9, wherein the metal atoms and the sacrificial target comprise the same material.

13. The processing chamber of claim 1, wherein the vaporized ligands comprise substituted or unsubstituted alkenes and alkynes, imines, heterocyclic compounds, chelating ligands, unsubstituted or substituted arenes, tertiary amines, tertiary phosphines, ethers, dienes, or combinations thereof.

14. A processing chamber comprising:
a chamber body having a top wall, a bottom wall, and two opposed sidewalls containing an interior volume;
a metal source within the interior volume to provide metal atoms to a precursor formation region within the interior volume;
a ligand source to provide vaporized ligands to the precursor formation region, wherein the metal atoms and the vaporized ligands react to form a metal-containing precursor; and
a substrate positioned on a substrate support within the interior volume, wherein the metal-containing precursor forms a metal film on the substrate.

15. A deposition method comprising:
forming a metal-containing precursor by providing metal atoms to a precursor formation region from a metal source, the metal source and the precursor formation region within an interior volume of a processing chamber, and providing vaporized ligands to the precursor formation region from a ligand source, wherein the metal atoms and the vaporized ligands react to form the metal-containing precursor; and
exposing a substrate surface to the metal-containing precursor to deposit a metal film.

16. The deposition method of claim 15, wherein the substrate surface comprises at least one EUV pellicle.

17. The deposition method of claim 15, further comprising a sacrificial target spaced a distance from the metal source on a side opposite of the precursor formation region.

18. The deposition method of claim 17, wherein the sacrificial target comprises a front face extending between peripheral edges of the target and some of the metal atoms are deposited on the front face of the sacrificial target.

19. The deposition method of claim 17, further comprising removing the sacrificial target from the interior volume.

20. The deposition method of claim 17, further comprising performing a metallurgic recovery process on the removed sacrificial target to recover some of the metal atoms.
